(19) United States
(12) Patent Application Publication
(10) Pub. No.: US 2012/0133346 A1
(43) Pub. Date: May 31, 2012

(54) SUCCESSIVE APPROXIMATION REGISTER A/D CONVERTER AND DC/DC CONVERTER

(75) Inventors: Taichi Ogawa, Tokyo (JP); Takeshi Ueno, Kawasaki-Shi (JP); Masanori Furuta, Odawara-Shi (JP); Takakazu Yoshida, Kawasaki-Shi (JP)

(73) Assignee: KABUSHIKI KAISHA TOSHIBA, Tokyo (JP)

(21) Appl. No.: 13/053,395

(22) Filed: Mar. 22, 2011

(30) Foreign Application Priority Data
Nov. 29, 2010 (JP) 2010-265373

(51) Int. Cl. G05F 1/10; H03M 1/12

(52) U.S. Cl. 323/282; 341/110

(57) ABSTRACT

The SAR control circuit of the successive approximation register A/D converter changes the digital value by the first conversion frequency in a first conversion range according to the comparison result signal, and outputs the digital value.

When it is determined that the sample and hold value is out of the first conversion range according to the determination signal, the range setting circuit sets a second conversion range different from the first conversion range.

### CROSS-REFERENCE TO RELATED APPLICATION

This application is based upon and claims the benefit of priority from the prior Japanese Patent Application No. 2010-265373, filed on Nov. 29, 2010, the entire contents of which are incorporated herein by reference.

### BACKGROUND

1. Field

Embodiments described herein relate generally to a successive approximation register A/D converter (SARADC) and a DC/DC converter.

2. Background Art

In general, a successive approximation register A/D converter (SARADC) compares an input voltage sampled and held by a sample and hold circuit and an analog voltage output from a D/A converter by a comparator, and executes an A/D conversion sequentially from upper bits.

Since the successive approximation register A/D converter according to the conventional art uses one comparator and does not use an amplifier, the successive approximation register A/D converter features a small scale of a circuit and low consumption in power.

In the conventional art, in the successive approximation register A/D converter, when a voltage range of the input signal is narrow in contrast to the full-scale conversion range where the A/D conversion can be executed, the number of conversion cycles may be reduced by narrowing the conversion range of the D/A converter.

### BRIEF DESCRIPTION OF THE DRAWINGS

FIG. 1 is a diagram showing an example of the configuration of a DC/DC converter 1000 according to a first embodiment;

FIG. 2 is a diagram showing an example of the configuration of the successive approximation register A/D converter 100 of the DC/DC converter 1000 shown in FIG. 1.;

FIG. 3 is a diagram showing an example of the conversion range of the successive approximation register A/D converter 100 shown in FIG. 2;

FIG. 4 is a diagram showing another example of the conversion range of the successive approximation register A/D converter 100 shown in FIG. 2;

FIG. 5 is a timing chart illustrating an example of the operation of the A/D conversion of the successive approximation register A/D converter 100 shown in FIG. 2;

FIG. 6 is a diagram showing an example of the configuration of a DC/DC converter 2000 according to the second embodiment;

FIG. 7 is a diagram showing an example of the configuration of the successive approximation register A/D converter 200 of the DC/DC converter 2000 shown in FIG. 6;

FIG. 8 is a timing chart illustrating an example of the A/D conversion operation of the successive approximation register A/D converter 200 shown in FIG. 7;

FIG. 9 is a diagram showing an example of the configuration of a DC/DC converter 3000 according to the third embodiment;

FIG. 10 is a diagram showing an example of a conversion range of the successive approximation register A/D converter 100 shown in FIG. 9;

FIG. 11 is a diagram showing an example of the configuration of a DC/DC converter 4000 according to the fourth embodiment;

FIG. 12 is a diagram showing an example of the configuration of a DC/DC converter 5000 according to a fifth embodiment; and

FIG. 13 shows an example of the configuration of the successive approximation register A/D converter 500 of the DC/DC converter 5000 shown in FIG. 12.

### DETAILED DESCRIPTION

A successive approximation register A/D converter according to an embodiment, executes an A/D conversion on an analog signal, and that outputs an obtained digital value. The successive approximation register A/D converter includes a first sample and hold circuit that receives a first voltage being an analog signal, and that outputs a sample and hold value obtained by sampling and holding the first voltage in synchronization with a first clock signal. The successive approximation register A/D converter includes a D/A converter that outputs a conversion value obtained by executing a D/A conversion on the digital value. The successive approximation register A/D converter includes a comparator that compares the sample and hold value and the conversion value, and that outputs a comparison result signal according to the comparison result. The successive approximation register A/D converter includes a SAR control circuit that changes the digital value by the set change frequency in the set conversion range to carry out binary search for the sample and hold value with the conversion value according to the comparison result signal, and outputs the digital value. The successive approximation register A/D converter includes a within/outside range determining circuit that determines whether the sample and hold value is within the set conversion range, on the basis of the comparison result signal and the conversion frequency, and outputs a determination signal according to the determination result. The successive approximation register A/D converter includes a range setting circuit that sets the conversion range on the basis of the determination signal.

The SAR control circuit changes the digital value by the first conversion frequency in a first conversion range according to the comparison result signal, and outputs the digital value.

When it is determined that the sample and hold value is out of the first conversion range according to the determination signal, the range setting circuit sets a second conversion range different from the first conversion range.

Hereafter, embodiments of the present invention will be described with reference to the drawings.

### First Embodiment

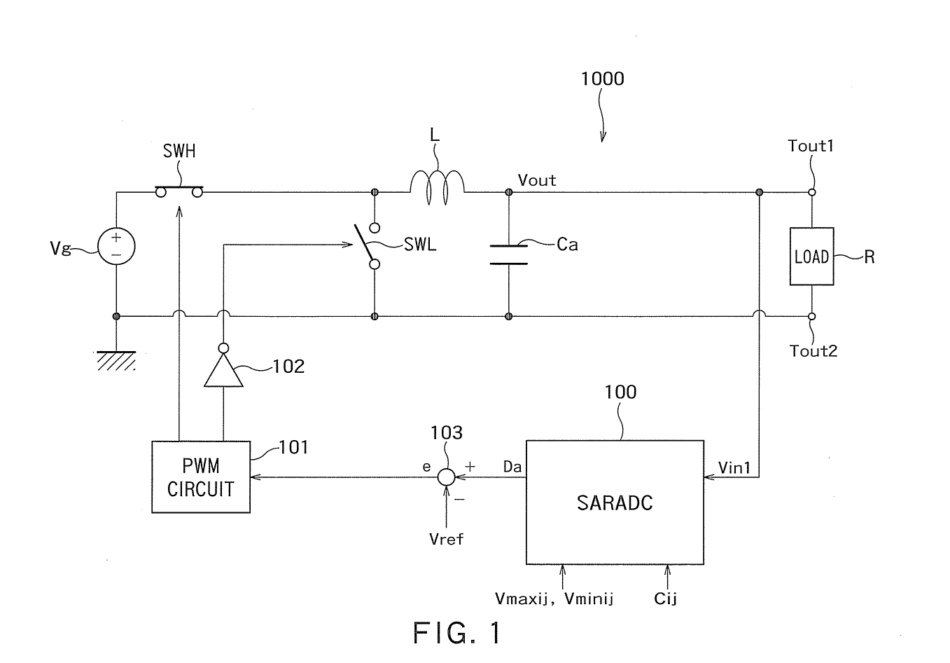

FIG. 1 shows an example of the configuration of a DC/DC converter 1000 according to a first embodiment.

As shown in FIG. 1, the DC/DC converter 1000 is a circuit that converts (controls) a power supply voltage (direct-current voltage) of a power supply Vg into an output voltage (direct-current voltage) Vout lower than the power supply voltage and supplies the resultant voltage to a load R.

The DC/DC converter 1000 includes a successive approximation register A/D converter 100, a pulse width modulation (PWM) circuit 101, an inverter 102, a comparator 103, a first output terminal Tout1, a second output terminal Tout2, a high-side switch SWH, a low-side switch SWL, a capacitor Ca, and an inductor L.

The first output terminal Tout1 is connected to one end of the capacitor Ca.

The second output terminal Tout2 is connected to the other end of the capacitor Ca.

The high-side switch SWH is, for example, a MOS transistor. One end (drain) of the high-side switch SWH is connected to one end (positive terminal) of the power supply Vg. One end of the inductor L is connected to the first output terminal Tout1, and the other end (source) of the high-side switch SWH is connected to the other end of the inductor L.

The low-side switch SWL is, for example, a MOS transistor. One end (drain) of the low-side switch SWL is connected to the other end (source) of the high-side switch SWH, and the other end (source) thereof is connected to the other end of the power supply Vg, the ground, and the other end of the capacitor Ca.

The successive approximation register A/D converter 100 executes the A/D conversion on an output voltage (first voltage) Vout that is an analog signal from the first output terminal Tout1 and outputs an obtained digital value Da (Dij).

The successive approximation register A/D converter 100 receives digital signals (minimum value Vminij and maximum value Vmaxij) to define a maximum value and a minimum value of the digital value Da (Dij) and also receives conversion frequency Cij that is a digital signal defining the execution frequency of the A/D conversion.

The comparator 103 carries out an operation on the difference between the digital value Da (Dij) and a reference voltage value Vref, and outputs an obtained error voltage e.

On the basis of the error voltage e, the PWM circuit 101 outputs a control signal to a gate of the high-side switch SWH and outputs the control signal to a gate of the low-side switch SWL through the inverter 102. Thereby, the PWM circuit 101 complementarily controls ON/OFF of the high-side switch SWH and the low-side switch SWL.

The capacitor Ca and the inductor L are coupled externally to an integrated circuit constituting the DC/DC converter 1000. However, the capacitor Ca and the inductor L may be integrally formed to be one integrated circuit.

The DC/DC converter 1000 that has the above-described configuration alternately turns on/off the high-side switch SWH and the low-side switch SWL and generates a rectangular-wave voltage. The DC/DC converter 1000 smoothes the obtained rectangular-wave voltage by the inductor L and the capacitor Ca and obtains the output voltage Vout that is the direct-current voltage.

The DC/DC converter 1000 changes a duty ratio of ON/OFF of the high-side switch SWH and the low-side switch SWL and controls the output voltage Vout.

In order to control the output voltage Vout, first, the DC-DC converter 1000 executes the A/D conversion on the output voltage Vout, subtracts the reference voltage value Vref of a desired voltage from a voltage obtained after the A/D conversion, and obtains the error voltage e. The error voltage e is input to the PWM circuit 101.

For example, when the error voltage e is positive, the PWM circuit 101 lowers a duty ratio of a pulse signal for controlling the high-side switch SWH (that is, lowers a ratio in which the high-side switch SWH is turned on). When the error voltage e is negative, the PWM circuit 101 raises the duty ratio of the pulse signal (that is, raises the ratio in which the high-side switch SWH is turned on).

By executing this feedback operation, the output voltage Vout is maintained at about the reference voltage value Vref.

Therefore, a first voltage Vin1 (output voltage Vout) that is input to the successive approximation register A/D converter 100 is generally maintained in a range of about the reference voltage value Vref.

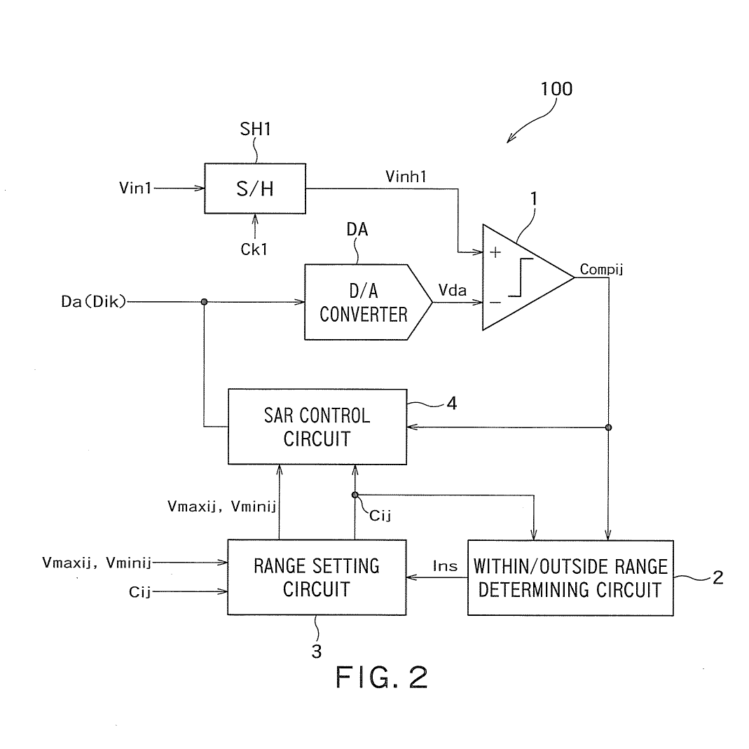

FIG. 2 shows an example of the configuration of the successive approximation register A/D converter 100 of the DC/DC converter 1000 shown in FIG. 1.

As shown in FIG. 2, the successive approximation register A/D converter 100 has a comparator 1, a within/outside range determining circuit 2, a range setting circuit 3, a SAR control circuit 4, a first sample and hold circuit SH1, and a D/A converter DA.

The first sample and hold circuit SH1 receives the first voltage Vin1 (output voltage Vout) that is an analog signal and outputs a sample and hold value Vinh1 that is obtained by sampling and holding the first voltage Vin1 in synchronization with a first clock signal Ck1.

That is, the first input voltage Vin1 that is the analog signal is sampled and held at timing of the clock signal Ck in the first sample and hold circuit SH1, and is input as a first sample and hold value Vinh1 to a non-inverting input terminal of the comparator 1.

The D/A converter DA outputs a conversion value Vda that is an analog value obtained by executing a D/A conversion on a digital value Da (Dij). The conversion value Vda is input to an inverting input terminal of the comparator 1.

The comparator 1 compares the sample and hold value Vinh1 with the conversion value Vda (that is, digital value Da), and outputs a comparison result signal Compij that is a 1-bit digital signal according to the comparison result.

For example, when the first sample and hold value Vinh1 is larger than the conversion value Vda, a value of the comparison result signal Compij is “1.”

Meanwhile, when the conversion value Vda is smaller than the first sample and hold value Vinh1, a value of the comparison result signal Compij is “0.”

The SAR control circuit 4 outputs the digital value Da (Dij) to the D/A converter DA. The digital value Da is an output of the successive approximation register A/D converter 100.

The SAR control circuit 4 changes the digital value Da within a set conversion range by the set frequency of conversion to perform binary search for the sample and hold value Vinh1 with the conversion value Vda (that is, digital value Da) according to the comparison result signal Comp and outputs the digital value. That is, the SAR control circuit 4 sequentially generates the digital value Da (Dij) using, for example, the principle of the binary search to be described below, such that the difference of the sample and hold value Vinh1 and the conversion value Vda decreases.

The within/outside range determining circuit 2 receives the conversion frequency Cij and the comparison result signal Compij.

The within/outside range determining circuit 2 determines whether the sample and hold value Vin1 is within the set conversion range, on the basis of the comparison result signal Compij and the conversion frequency Cij, and outputs a determination signal Ins according to the determination result.

For example, when values of all of the comparison result signals Compij corresponding to the conversion frequency Cij of the certain conversion range are “1” (that is, when the sample and hold values are larger than a maximum value in the conversion range), the within/outside range determining circuit 2 sets a level of the determination signal Ins to a “High” level.

When the values of all of the comparison result signals Compij corresponding to the conversion frequency Cij of the certain conversion range are “0” (that is, when the sample and hold values are smaller than a minimum value in the conversion range), the within/outside range determining circuit 2 sets a level of the determination signal Ins to a “Low” level.

When the values of all of the comparison result signals Compij corresponding to the conversion frequency Cij of the certain conversion range are neither “0” nor “1” (that is, when the sample and hold values are within the conversion range), the within/outside range determining circuit 2 sets a level of the determination signal Ins to a “Mid” level.

The digital signals (minimum value Vminij and maximum value Vmaxij) to define the maximum value and the minimum value of the digital value Da (Dij) and the conversion frequencies Cij corresponding to the digital signals to define the frequency of the A/D conversion in the certain conversion range are input from the outside of the successive approximation register A/D converter 100 to the range setting circuit 3.

The range setting circuit 3 sets the conversion range on the basis of the input digital signals and determination signals Ins. For example, the range setting circuit 3 determines the conversion range and the conversion frequency Cij to be selected from the plural conversion ranges (minimum value Vminij and maximum value Vmaxij) and the plural conversion frequencies Cij, on the basis of the determination signal Ins from the within/outside range determining circuit 2.

Next, an example of the operation of the successive approximation register A/D converter 100 that has the above-described configuration will be described.

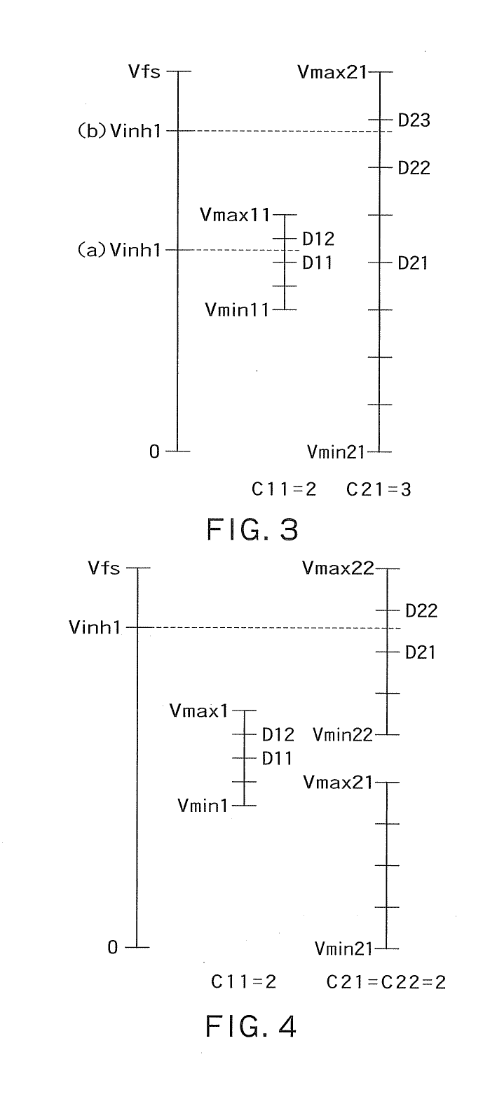

FIG. 3 shows an example of the conversion range of the successive approximation register A/D converter 100 shown in FIG. 2.

As shown in FIG. 3, first, one first conversion range (minimum value Vmin11 and maximum value Vmax11) is set to about the middle of a full-scale conversion range (0 to Vfs), the first conversion frequency C11 of the A/D conversion of the first conversion range is set to 2, and these values are input to the range setting circuit 3. The full-scale conversion range (0 to Vfs) is a maximum range of the first voltage Vin1 (first sample and hold value Vinh1) where the successive approximation register A/D converter 100 can execute the A/D conversion.

The successive approximation register A/D converter 100 executes successive approximation on the first sample and hold value Vinh1 by the first conversion frequency C11 (2), in the first conversion range (minimum value Vmin11 to maximum value Vmax11).

In this case, since the first conversion frequency C11 is 2, the first conversion range (minimum value Vmin11 to maximum value Vmax11) is divided by 2^{C1} (=4), and the conversion range that includes the first sample and hold value Vinh1 among the conversion ranges divided by 4 is determined.

In an initial state, the SAR control circuit 4 inputs a digital signal D11 having a value represented by the following equation 1 to the D/A converter DA.

D11=(Vmax11−Vmin11)/2 (1)

First, an operation of the case where the first input voltage Vin1 (first sample and hold value Vinh1) is within the first conversion range (minimum value Vmin11 to maximum value Vmax11) (the case of an example (b) of the first sample and hold value Vinh1) will be described.

In an example (a) of FIG. 3, since the first sample and hold value Vinh1 is larger than the digital value D11, a value of the comparison result signal Comp11 becomes “1.”

A digital value D12 that is obtained by the second A/D conversion in the first conversion range becomes an intermediate voltage between the digital value D11 and the maximum value Vmax11 by the principle of the binary search. Since the first sample and hold value Vinh1 is smaller than the digital value D12, a value of the comparison result signal Comp11 becomes “0.”

By the two successive approximations, the first sample and hold value Vinh1 exists within a range represented by the following equation 2.

D11<Vinh1<D12 (2)

Therefore, the final digital value D12 becomes the result of the final A/D conversion of the first sample and hold value Vinh1. At this time, the within/outside range determining circuit 2 outputs a determination signal Ins1 having a “Mid” level. The determination signal Ins being at “Mid” level means an end of the A/D conversion.

In this conversion, resolution RE1 is represented by the following equation 3.

RE1=(Vmax11−Vmin11)/2^{c11} (3)

Meanwhile, resolution RE2 is obtained when the successive approximation is executed on the entire full-scale conversion range by C11 without limiting the conversion range by the minimum value Vmin11 and the maximum value Vmax11, and the resolution RE2 is represented by the following equation 4.

RE2=Vfs/2^{c11} (4)

From the equations 3 and 4, it can be seen that the resolution more increases in the first conversion frequency C11, as the first conversion range (minimum value Vmin11 to maximum value Vmax11) is made narrower.

As the first conversion range (minimum value Vmin11 to maximum value Vmax11) is made narrower at the same resolution, the first conversion frequency C11 can be more decreased.

Next, an operation of the case where the first input voltage Vin1 (first sample and hold value Vinh1) is out of the first conversion range (minimum value Vmin11 to maximum value Vmax11) (the case of the example (b) of the first sample and hold value Vinh1) will be described.

In the example (b) of FIG. 3, the digital value D11 becomes an intermediate potential between the minimum value Vmin11 and the maximum value Vmax11 by the first A/D conversion.

A digital value D12 that is obtained by the second A/D conversion is an intermediate voltage between the digital value D11 and the maximum value Vmax11.

Therefore, values of both the first and second comparison result signals Comp11 and Comp12 are “1.”

Thereby, a level of the determination signal Ins1 becomes a “High” level. That is, since the level of the determination signal Ins1 is not a “Mid” level, the successive approximation register A/D converter 100 continuously executes the A/D conversion.

The range setting circuit 3 receives the determination signal Ins1 being at “High” level and outputs another conversion range (minimum value Vminij and maximum value Vmaxij) and a value of a conversion frequency Cij having been stored in advance, that is, a minimum value Vmin21 and a maximum value Vmax21 indicating the other second conversion range and the second conversion frequency C21 for executing successive approximation in the second conversion range to the SAR control circuit 4.

An example of FIG. 3 is an example of the case where minimum value Vmin21=0, maximum value Vmax21=Vfs, and conversion frequency C21=3. In this example, the successive approximation in the entire full-scale conversion range is executed three times.

By setting the other second conversion range, the A/D conversion can be securely executed on the first sample and hold value Vinh1, even though the first sample and hold value Vinh1 is an arbitrary value in the full-scale conversion range.

The first sample and hold value Vinh1 is converted into a digital value D23 by five A/D conversions (i.e. the first conversion frequency C11 (2 conversions)+second conversion frequency C21 (3 conversions)).

In the operation of the successive approximation register A/D converter 100, when the first input voltage Vin1 is out of the conversion range (minimum value Vmin11 to maximum value Vmax11), the two unnecessary conversion operations need to be executed, despite of having the same conversion precision as an A/D converter where minimum value Vmin11=0, maximum value Vmax11=Vfs, and conversion frequency C11=3 are set.

However, if the probability of the input voltage Vin1 being out of the conversion range (minimum value Vmin11 to maximum value Vmax11) is low, the conversion frequency of the A/D conversion can be the conversion frequency C1 (2) and resolution can be increased. In this case, consumption power and a conversion time can be decreased.

Unlike the conventional art, even when the input voltage is out of the conversion range (minimum value Vmin11 to maximum value Vmax11), the A/D conversion can be executed.

Next, an example of the case where two second conversion ranges (Vmin2 and Vmax2) are set will be described.

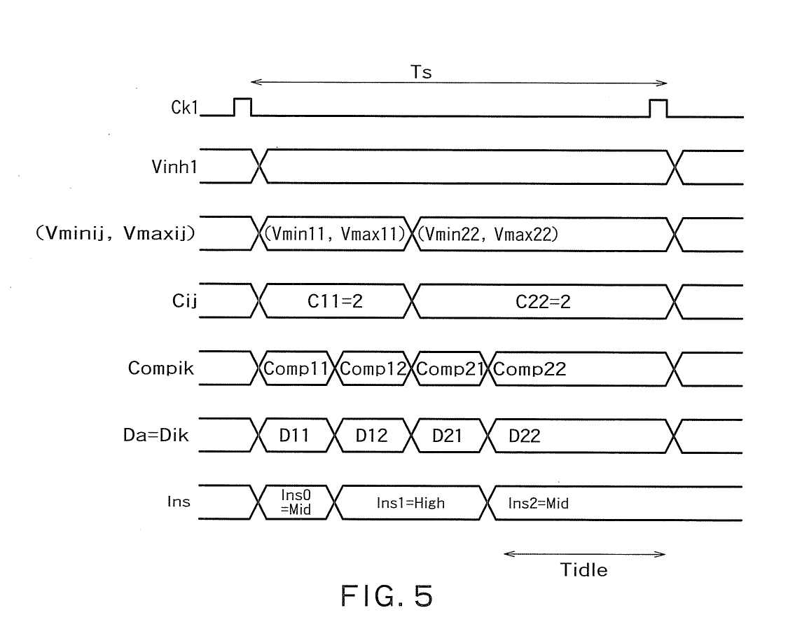

FIG. 4 shows another example of the conversion range of the successive approximation register A/D converter 100 shown in FIG. 2.

As shown in FIG. 4, the plural (in this case, two) second conversion ranges are set with different ranges (minimum value Vmin21 and maximum value Vmax21) and (minimum value Vmin22 and maximum value Vmax22).

In an example of FIG. 4, the operation until the successive approximation register A/D converter 100 outputs the digital values D11 and D12 is the same as that of the case of FIG. 3.

That is, when the comparison result signal Comp12 is output, a level of the determination signal Ins becomes a “High” level and the first sample and hold value Vinh1 is larger than the digital value D12.

Therefore, the second conversion range (minimum value Vminij to maximum value Vmaxij) should exceed the digital value D12.

Therefore, the range setting circuit 3 selects the minimum value Vmin22 and the maximum value Vmax22 that indicate the higher second conversion range of the two conversion ranges (minimum value Vmin21 and maximum value Vmax21) and (minimum value Vmin22 and maximum value Vmax22), and outputs the minimum value Vmin22 and the maximum value Vmax22 to the SAR control circuit 4.

As such, the plural second conversion ranges that are set when the values of the first conversion range exceed the first sample and hold value Vinh1 are prepared. According to the result of the A/D conversion with respect to the first conversion range, one second conversion range is selected.

Thereby, the second conversion range becomes narrower than the full-scale conversion range and high-precision conversion can be executed with the smaller conversion frequency.

In an example of FIG. 4, the range width of one second conversion range (minimum value Vmin21 to maximum value Vmax21) and the range width of the other second conversion range (minimum value Vmin22 to maximum value Vmax22) are equal to each other. In both the conversion ranges, the conversion frequencies C21 and C22 are equal and they are set to 2. However, the range widths and the conversion frequencies may be set to be different from each other, according to necessity.

As shown in FIG. 4, timing of each signal in the case where the A/D conversion is executed will be described. FIG. 5 is a timing chart illustrating an example of the operation of the A/D conversion of the successive approximation register A/D converter 100 shown in FIG. 2.

In FIG. 5, one cycle of a clock signal Ck1 that is input to the first sample and hold circuit SH1 is set to Ts.

The first sample and hold circuit SH1 holds an input voltage Vin at the time when a level of the clock signal Ck changes from a “High” level to a “Low” level.

Therefore, the sample and hold value Vinh is held during a period where the level of the clock signal Ck is a “Low” level.

At a head of one cycle of the first clock signal Ck1, the within/outside range determining circuit 2 sets an initial value of the determination signal Ins as determination signal Ins0 being at “Mid” level. In the initial state, the range setting circuit 3 outputs the first conversion range (minimum value Vmin11 and maximum value Vmax11) and the first conversion frequency C11.

Since the conversion frequency C11 is 2, the comparator 1 executes the two comparison operations and sequentially outputs the comparison result signals Comp11 and Comp12. At this time, the SAR control circuit 4 sequentially outputs the digital values D11 and D12. That is, the SAR control circuit 4 changes the digital value Dij by the first conversion frequency Cij within the first conversion range according to the comparison result signal Compij and outputs the digital value.

When the comparison result signal Comp12 is output, the within/outside range determining circuit 2 determines that the values of both the comparison result signals Comp11 and Comp12 when conversion frequency C11=2 are “1.” Thereby, the within/outside range determining circuit 2 outputs a determination signal Ins1 being at “High” level.

That is, the within/outside range determining circuit 2 outputs the determination signal Ins1 according to a positional relationship of the first conversion range and the first sample and hold value Vinh1, on the basis of the comparison result signals Comp11 and Comp12.

Therefore, the range setting circuit 3 outputs the second conversion range (minimum value Vmin22 and maximum value Vmax22) and the second conversion frequency C22 (2) to the SAR control circuit 4 in order to execute the third and following A/D conversions after the A/D conversion of the first conversion frequency C11 (2).

That is, the range setting circuit 3 selects and sets one second conversion range from the plural second conversion ranges on the basis of the positional relationship, when it is determined that the first sample and hold value Vinh1 is out of the first conversion range according to the determination signal Ins1.

When the comparison result signal Comp22 is output from the comparator 1, the within/outside range determining circuit 2 determines that values of both the comparison result signals Comp21 and Comp22 of the second conversion frequency C22 (2) are “1.” Thereby, the within/outside range determining circuit 2 outputs a determination signal Ins2 being at “Mid” level.

At this time, the successive approximation register A/D converter 100 ends the A/D conversion. That is, the SAR control circuit 4 continuously outputs the digital value D22 until a next clock cycle and the successive approximation register A/D converter 100 holds an output of the digital value D22 as a final digital value Da from the A/D conversion.

As such, according to the successive approximation register A/D converter according to the first embodiment, the conversion ranges of the input signals can be appropriately set and the conversion cycles of the input signals can be decreased.

As described above, the DC/DC converter 1000 maintains the output voltage Vout about the reference voltage value Vref by the feedback operation. Thereby, the first input voltage Vin1 of the successive approximation register A/D converter 100 is generally maintained about the reference voltage value Vref. That is, the frequency of the A/D conversion can be decreased by applying the successive approximation register A/D converter 100 to the DC/DC converter 1000.

### Second Embodiment

In FIG. 5 described above, during an idle period Tidle from a point of time when a level of the determination signal Ins2 becomes a “Mid” level to a next clock cycle, the successive approximation register A/D converter does not execute the A/D conversion and is maintained in an idle state.

In the example of FIG. 5, the input voltage exists in the second conversion range (minimum value Vmin22 to maximum value Vmax22). If an input voltage Vin1 exists in the first conversion range (minimum value Vmin11 to maximum value Vmax11), the idle period Tidle increases.

Therefore, in a second embodiment, an example of the configuration of the successive approximation register A/D converter that executes the A/D conversion on another input signal using the idle period Tidle will be described.

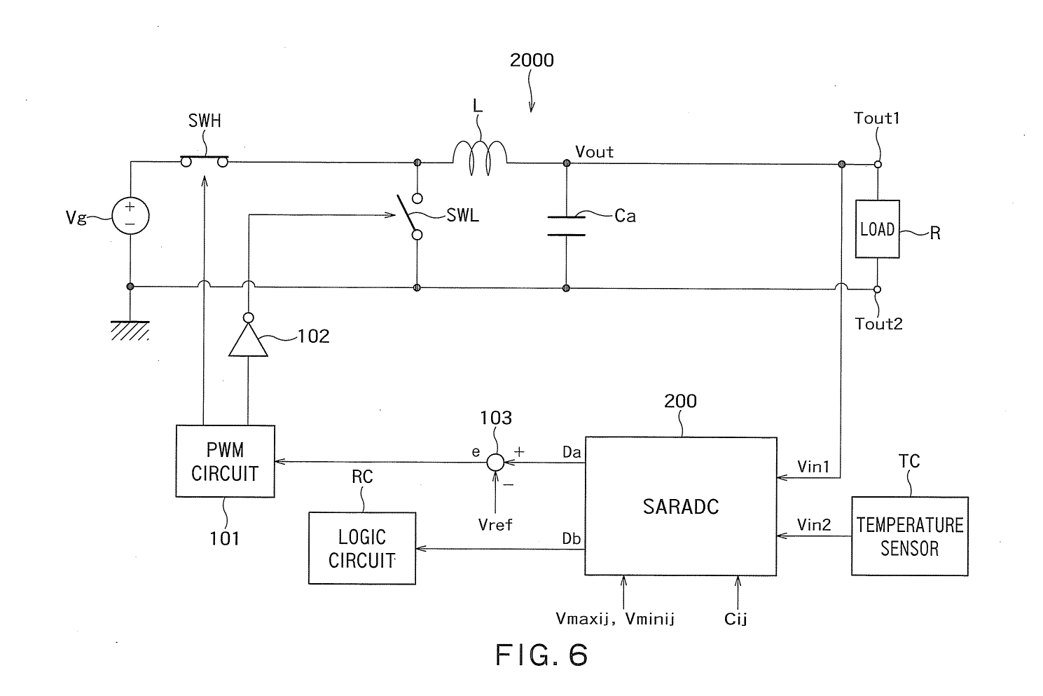

FIG. 6 shows an example of the configuration of a DC/DC converter 2000 according to the second embodiment. In FIG. 6, the same reference numerals as those of FIG. 1 denote the same components as those of the first embodiment.

As shown in FIG. 6, the DC/DC converter 2000 includes a successive approximation register A/D converter 200, a PWM circuit 101, an inverter 102, a comparator 103, a first output terminal Tout1, a second output terminal Tout2, a high-side switch SWH, a low-side switch SWL, a capacitor Ca, an inductor L, a temperature sensor TC, and a logic circuit RC.

That is, the DC/DC converter 2000 further includes the temperature sensor TC and the logic circuit RC, as compared with the DC/DC converter 1000 according to the first embodiment.

The temperature sensor TC senses the temperature of the DC/DC converter 2000 and outputs a second voltage Vin2 to the successive approximation register A/D converter 200 according to the temperature.

The successive approximation register A/D converter 200 executes the A/D conversion on the first voltage Vin1 and outputs a digital value Da, and executes the A/D conversion on the second voltage Vin2 and outputs a digital value Db.

The logic circuit RC is a storage device that stores the digital value Da obtained by executing the A/D conversion on the second voltage Vin2, a control circuit that executes predetermined processing according to the digital value Db, and the like.

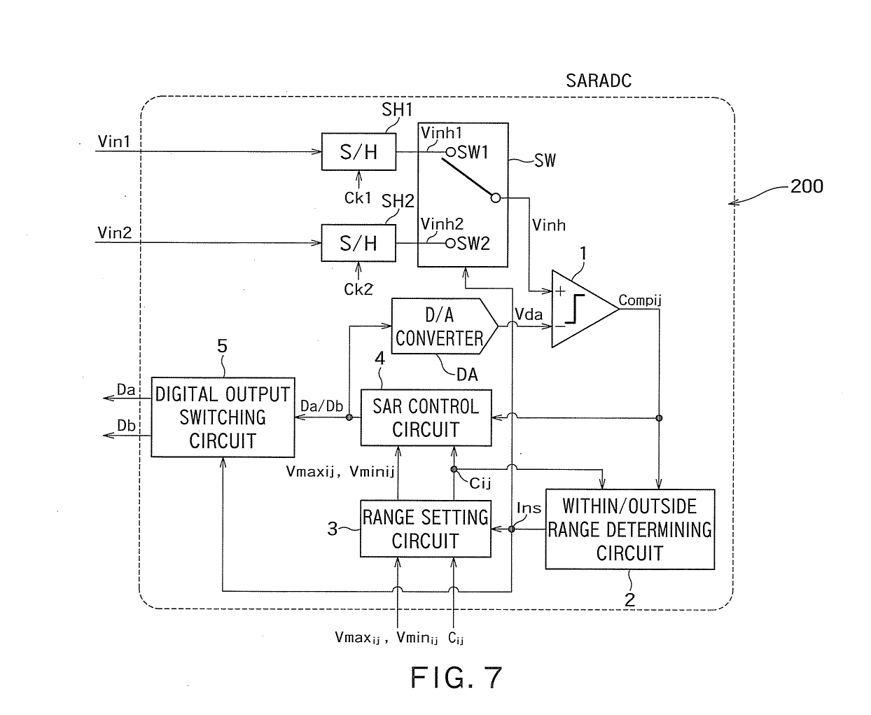

FIG. 7 shows an example of the configuration of the successive approximation register A/D converter 200 of the DC/DC converter 2000 shown in FIG. 6. In FIG. 7, the same reference numerals as those of FIG. 2 denote the same components as those of the first embodiment.

As shown in FIG. 7, the successive approximation register A/D converter 200 has a comparator 1, a within/outside range determining circuit 2, a range setting circuit 3, a SAR control circuit 4, a first sample and hold circuit SH1, a second sample and hold circuit SH2, a D/A converter DA, a switch SW, and a digital output switching circuit 5.

That is, the successive approximation register A/D converter 200 further has the second sample and hold circuit SH2, the switch SW, and the digital output switching circuit 5, as compared with the successive approximation register A/D converter 100 according to the first embodiment.

The second sample and hold circuit SH2 receives the second voltage Vin2 that is an analog signal and outputs a second sample and hold value Vinh2 that is obtained by sampling and holding the second voltage Vin2 in synchronization with a second clock signal Ck2 having a cycle longer than the cycle of the first clock signal Ck1.

As such, the successive approximation register A/D converter 200 samples and holds the first input voltage Vin1 and the second input voltage Vin2, which are two analog signals, by the first sample and hold circuit SH1 and the second sample and hold circuit SH2, respectively.

As described above, the first sample and hold circuit SH1 and the second sample and hold circuit SH2 receive the first clock signal Ck1 and the second clock signal Ck2 different from each other, respectively.

The switch circuit SW switches an output (first sample and hold value Vinh1) of the first sample and hold circuit SH1 and an output (second sample and hold value Vinh2) of the second sample and hold circuit SH2 according to the determination signal Ins, and outputs the sample and hold value Vinh.

In an initial state, the switch circuit SW is connected to a terminal SW1. That is, the successive approximation register A/D converter 200 starts the A/D conversion on the first input voltage Vin1 by the same operation as that of the first embodiment, in synchronization with the first clock signal Ck1.

When the A/D conversion of the first input voltage Vin1 is completed, the switch circuit SW is switched from the terminal SW1 to a terminal SW2.

That is, when it is determined that the sample and hold value Vinh1 of the first sample and hold circuit SH1 is within the first conversion range according to the determination signal Ins, the switch circuit SW switches the output from the output of the first sample and hold circuit SH1 to the output of the second sample and hold circuit SH2, and outputs an output voltage.

The successive approximation register A/D converter 200 executes the A/D conversion on the input voltage Vin2 using the idle period Tidle.

The digital output switching circuit 5 receives the digital values Da and Db that are output from the SAR control circuit 4.

The digital output switching circuit 5 switches a digital value Da corresponding to the output (first sample and hold value Vin1) of the first sample and hold circuit SH1 and a digital value Da corresponding to the output (second sample and hold value Vinh2) of the second sample and hold circuit SH2 according to the determination signal Ins, and outputs the digital values.

For example, when it is determined that the sample and hold value Vinh1 of the first sample and hold circuit SH1 is within the first conversion range according to the determination signal Ins (“Mid” level), the digital output switching circuit 5 switches the digital value from the digital value Da corresponding to the output of the first sample and hold circuit SH1 to the digital value Da corresponding to the output of the second sample and hold circuit SH2, and outputs the digital value.

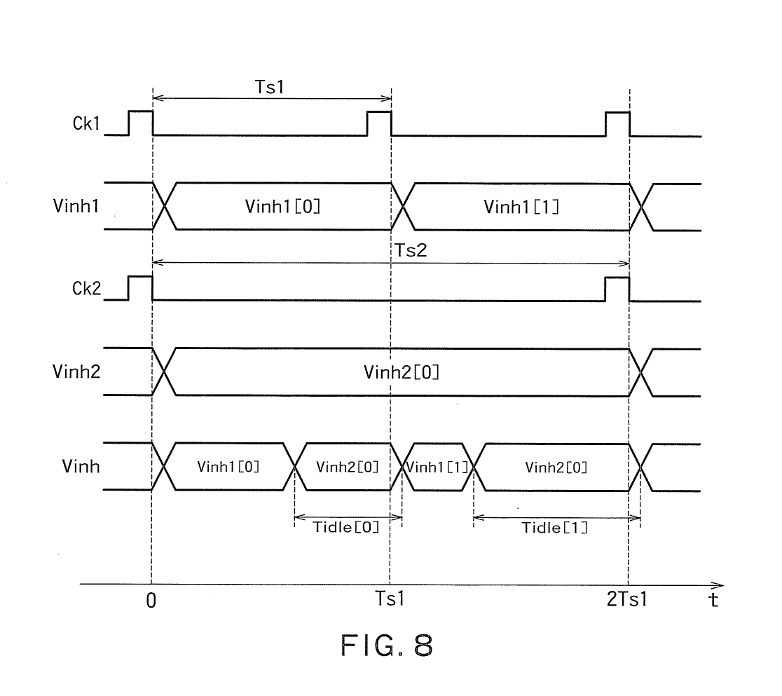

FIG. 8 is a timing chart illustrating an example of the A/D conversion operation of the successive approximation register A/D converter 200 shown in FIG. 7.

As shown in FIG. 8, the first input voltage Vin1 is held at timing when the clock signal Ck1 falls and is input as the first sample and hold value Vinh1[0].

As described above, the first sample and hold circuit SH1 holds the first voltage Vin1 for each cycle Ts1 of the first clock signal Ck1. At timing when the cycle becomes the cycle Ts1 n (integer) times as long as the cycle, the switch circuit SW is switched into the SW1 side.

Thereby, the successive approximation register A/D converter 200 executes the A/D conversion on the first sample and hold value Vinh1.

Meanwhile, the second sample and hold value Vinh2 that is obtained by sampling and holding the second input voltage Vin2 is held during a period of a cycle Ts2 of the second clock signal Ck2 that is longer than the cycle Ts1 of the first clock signal Ck1.

When a time needed to execute the A/D conversion on the first sample and hold value Vinh1 [0] is shorter than the cycle Ts1 and the idle period Tidle [0] exists, in the idle period Tidle [0], the switch can be switched into the terminal SW2 side and the A/D conversion on the second sample and hold value Vinh2 [0] can be started.

As shown in FIG. 8, when time t becomes equal to Ts1 in the middle of the A/D conversion on the second sample and hold value Vinh2 [0], the SAR control circuit 4 holds the conversion result of the second sample and hold value Vinh2 [0].

The switch circuit SW is switched into the terminal SW1 again and the successive approximation register A/D converter 200 starts the A/D conversion on a next first sample and hold value Vinh1 [1].

If the A/D conversion on the next first sample and hold value Vinh1 [1] is completed, the A/D conversion on a second sample and hold value Vinh2 [0] restarts using a next idle period Tidle [1].

During a period in which 0<t<Ts2, the second input voltage Vin2 is held as a second sample and hold value Vinh2 [0] in the second sample and hold circuit SH2. Therefore, the successive approximation register A/D converter 200 can execute the A/D conversion on the input voltage Vin2 using the idle period Tidle [0] and the next idle period Tidle [1] separated from each other.

In this A/D conversion, the digital output switching circuit 5 divides the results of the A/D conversion on the first and second input voltages Vin1 and Vin2 into the digital value Da and the digital value Db, and outputs the results from the different terminals.

When the level of the determination signal Ins becomes a “Mid” level during the A/D conversion of the first sample and hold value Vinh1, the digital output switching circuit 5 outputs the result of the A/D conversion on the first input voltage Vin1 as D1.

Meanwhile, when the level of the determination signal Ins becomes a “Mid” level during the A/D conversion of the second sample and hold value Vinh2, the digital output switching circuit 5 outputs the result of the A/D conversion on the first input voltage Vin1 as D2 from the different terminal.

That is, when it is determined that the sample and hold value Vinh1 of the first sample and hold circuit SH1 is within the first conversion range according to the determination signal Ins (“Mid” level), the digital output switching circuit 5 switches the digital value from the digital value Da corresponding to the output of the first sample and hold circuit SH1 to the digital value Db corresponding to the output of the second sample and hold circuit SH2, and outputs the digital value.

As described above, if the range of the first input voltage Vin1 generally falls within the predetermined range, the A/D conversion of the first input voltage Vin1 is completed in a short period of time, and the plural long idle periods Tidle are generated.

Thereby, the plural A/D conversions can be executed by one successive approximation register A/D converter 200 and power consumption or a circuit area can be reduced.

As described above, according to the successive approximation register A/D converter according to the second embodiment, the conversion ranges of the input signals can be appropriately set and the conversion frequencies of the input signals can be reduced.

In the power supply circuit such as the DC/DC converter 2000, a temperature sensor that monitors the operation temperate and informs the external device of the operation temperature may be mounted. In the conventional art, an A/D converter is prepared for a temperature sensor and converts a signal from the temperature sensor into a digital signal.

By using the successive approximation register A/D converter 200 having the plural inputs described in the second embodiment, the A/D converter for the DC/DC output signal conversion and the A/D converter for the sensor signal conversion can be integrated. Therefore, the circuit area can be reduced.

In general, the sampling speed of the A/D converter for the DC/DC output signal conversion is about several MHz. Meanwhile, the sampling speed of the A/D converter for the sensor signal conversion is about several tens kHz and is very slow.

Therefore, the A/D conversion can be easily executed on the signal from the temperature sensor with the slow change using the plural idle periods generated in the A/D conversion of the DC/DC output.

### Third Embodiment

In a third embodiment, an example of the configuration of setting a conversion range for a soft start in the case where the soft start is executed at the time of starting an operation of a DC/DC converter will be described.

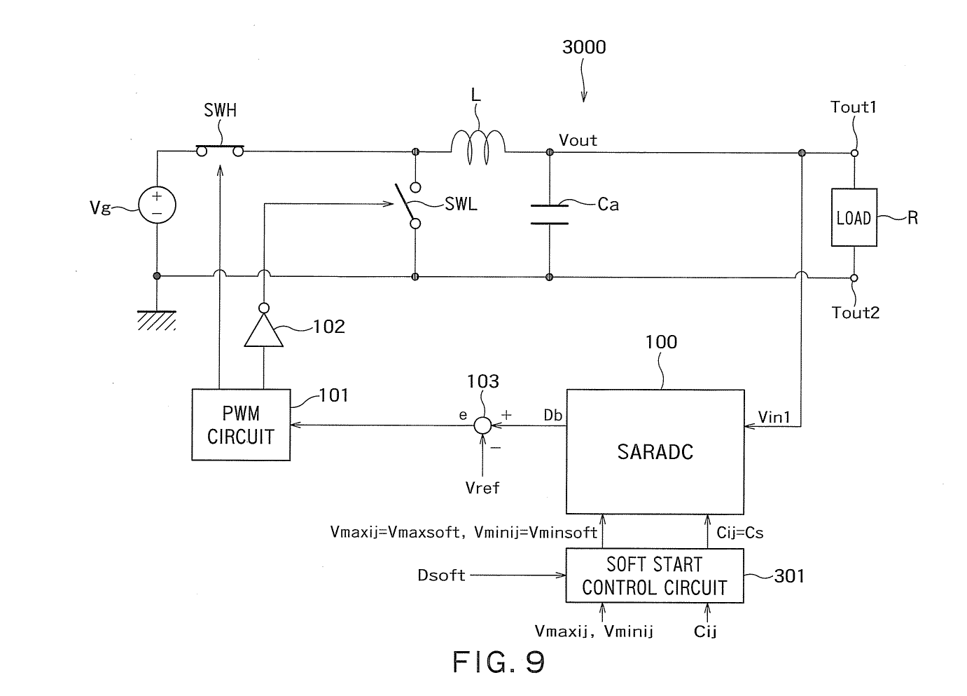

FIG. 9 shows an example of the configuration of a DC/DC converter 3000 according to the third embodiment. In FIG. 9, the same reference numerals as those of FIG. 1 denote the same components as those of the first embodiment.

As shown in FIG. 9, the DC/DC converter 3000 includes a successive approximation register A/D converter 100, a PWM circuit 101, an inverter 102, a soft start control circuit 301, a comparator 103, a first output terminal Tout1, a second output terminal Tout2, a high-side switch SWH, a low-side switch SWL, a capacitor Ca, and an inductor L.

That is, the DC/DC converter 3000 further includes the soft start control circuit 301, as compared with the DC/DC converter 1000 according to the first embodiment.

The soft start control circuit 301 receives a signal Dsoft, digital signals (minimum value Vminij and maximum value Vmaxij), and a conversion frequency Cij that is a digital signal for defining the execution frequency of the A/D conversion in a certain conversion range.

When the first voltage Vin1 increases from a ground voltage (0 V) according to the signal Dsoft, the soft start control circuit 301 sets a conversion range (minimum value Vminsoft and maximum value Vmaxsoft) for the soft start and a conversion range Cs for the soft start.

In this case, in the DC/DC converter 3000, when the operation starts, the voltage changes from an output voltage Vout=0 V to a reference voltage Vref.

At this time, an error voltage e by the comparator 103 to which the output voltage Vout (digital value Da) and the reference voltage Vref are input is greatly increased. For this reason, an ON time is increased, causing a problem in which an overcurrent flows through the PWM circuit 101.

If the overcurrent flows, the inductor L or the load R is broken and power that is input to the DC/DC converter 3000 may be shut down.

The overcurrent flows because the ON time of the high-side switch SWH is increased. The soft start needs to be executed to control the ON time not to cause the overcurrent to flow. There are three major methods for the soft start.

A first method is to change the ON time of the high-side switch SWH for the soft start by the PWM circuit 101 in advance. In the first method, the ON time is controlled to be gradually increased, regardless of the error voltage e.

A second method is to gradually change the reference voltage Vref. In the second method, since the large error voltage e is not input to the PWM circuit 101 by changing the reference voltage Vref from a low voltage, the ON time is gradually changed.

A third method is to change the output voltage Vout after sensing the output voltage. In the third method, by adding a correction voltage to the output voltage Vout and setting a limit voltage to the output voltage Vout, the comparator 103 is controlled not to output the large error voltage e.

In any of the three methods, since the input voltage and the output voltage Vout with respect to the successive approximation register A/D converter 100 gradually change from 0 V to the reference voltage Vref, an input range according to the voltage change is determined and the conversion frequency is greatly reduced.

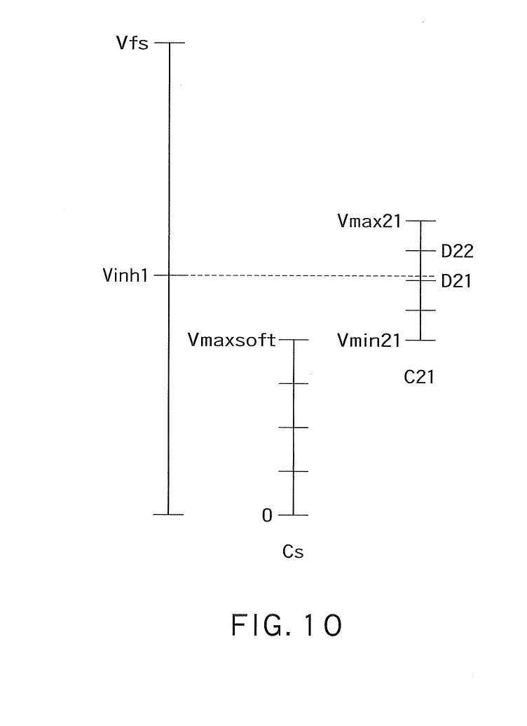

FIG. 10 shows an example of a conversion range of the successive approximation register A/D converter 100 shown in FIG. 9.

For example, as shown in FIG. 10, when the first voltage Vin1 increases from the ground voltage (0 V) at the time of the soft start, the conversion range for the soft start is set from the minimum value Vminsoft for the soft start to the maximum value Vmaxsoft for the soft start. That is, the minimum value of one first conversion range is set to the ground voltage and the maximum value Vmaxsoft of the first conversion range is set to the minimum value Vmin21 of the other second conversion range. In FIG. 10, the other first conversion range is set to correspond to one first conversion range in the first embodiment.

Thereby, the output voltage Vout that gradually increases is always within the first conversion range and the A/D conversion of the maximum value Vmaxsoft for the soft start or more is not executed. Thereby, the conversion range can be appropriately set.

If the output voltage Vout exceeds the maximum value Vmaxsoft for the soft start, the conversion range is set to a range about the reference voltage Vref.

By the above operation, the first voltage Vin1 (output voltage Vout) always exists in the conversion range and the conversion range can become narrower than the full-scale conversion range. Therefore, the operation can be efficiently executed.

As described above, according to the successive approximation register A/D converter according to the third embodiment, the conversion ranges of the input signals can be appropriately set and the conversion frequencies of the input signals can be reduced.

### Fourth Embodiment

In some types of architecture of the DC/DC converter, a change in the output voltage Vout can be predicted.

For example, when the load R is a central processing unit (CPU), if an operation rate changes from 20% to 100%, a load current rapidly increases and the output voltage Vout rapidly decreases.

At this time, the output voltage Vout may be out of the conversion range of the output voltage Vout that is initially set in the successive approximation register A/D converter 100.

Therefore, by inputting the increase/decrease of the load current to the successive approximation register A/D converter 100 in advance and predicting the change in the output voltage Vout, the output voltage Vout can be changed such that the conversion range thereof is not to be out of the set conversion range.

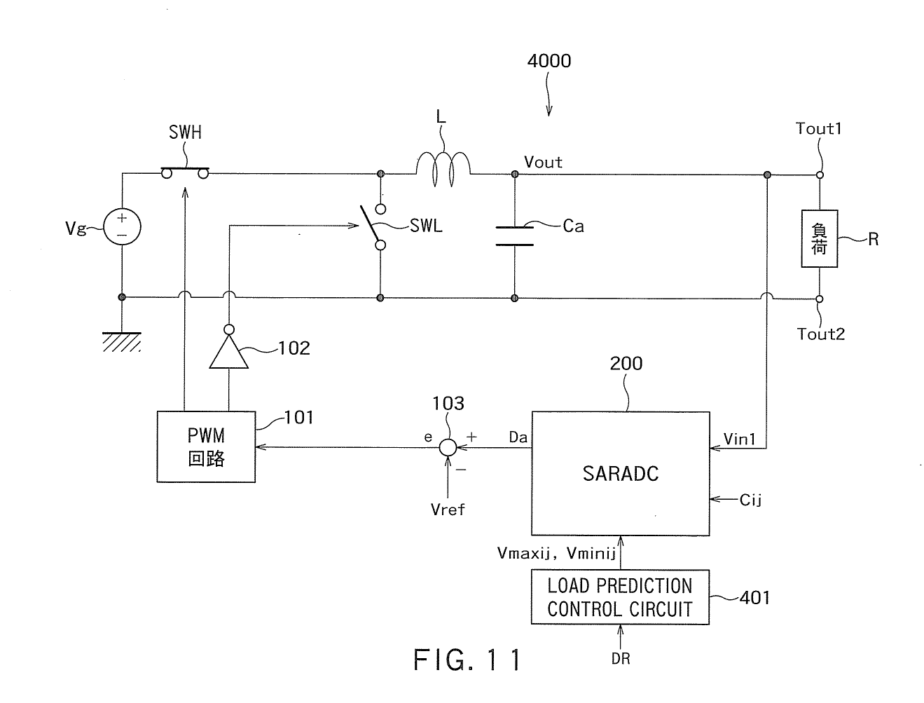

FIG. 11 shows an example of the configuration of a DC/DC converter 4000 according to the fourth embodiment. In FIG. 11, the same reference numerals as those of FIG. 1 denote the same components as those of the first embodiment.

As shown in FIG. 11, the DC/DC converter 4000 includes a successive approximation register A/D converter 100, a PWM circuit 101, an inverter 102, a comparator 103, a load prediction control circuit 401, a first output terminal Tout1, a second output terminal Tout2, a high-side switch SWH, a low-side switch SWL, a capacitor Ca, and an inductor L.

That is, the DC/DC converter 4000 further includes the load prediction control circuit 401, as compared with the DC/DC converter 1000 according to the fourth embodiment.

The load prediction control circuit 401 adjusts a first conversion range according to a prediction value DR of the increase/decrease of the load current flowing to the load R.

Since the output voltage Vout decreases when the load current increases, the load prediction control circuit 401 sets the conversion range such that the output voltages are low. Since the output voltage increases when the load current decreases, the load prediction control circuit 401 sets the conversion range such that the output voltages are high.

As described above, according to the successive approximation register A/D converter according to the fourth embodiment, the conversion ranges of the input signals can be appropriately set and the conversion frequencies of the input signals can be reduced.

### Fifth Embodiment

By controlling the output current of the DC/DC converter, the DC/DC converter can be stably controlled. Therefore, by changing the output current into the voltage by a current/voltage conversion and inputting the voltage to a SARADC, the current can be controlled. In this case, the conversion range of the successive approximation register A/D converter is limited.

At the same time, It is required that the successive approximation register A/D converter can sense an output voltage Vout.

The successive approximation register A/D converter needs to switch between two different conversion ranges.

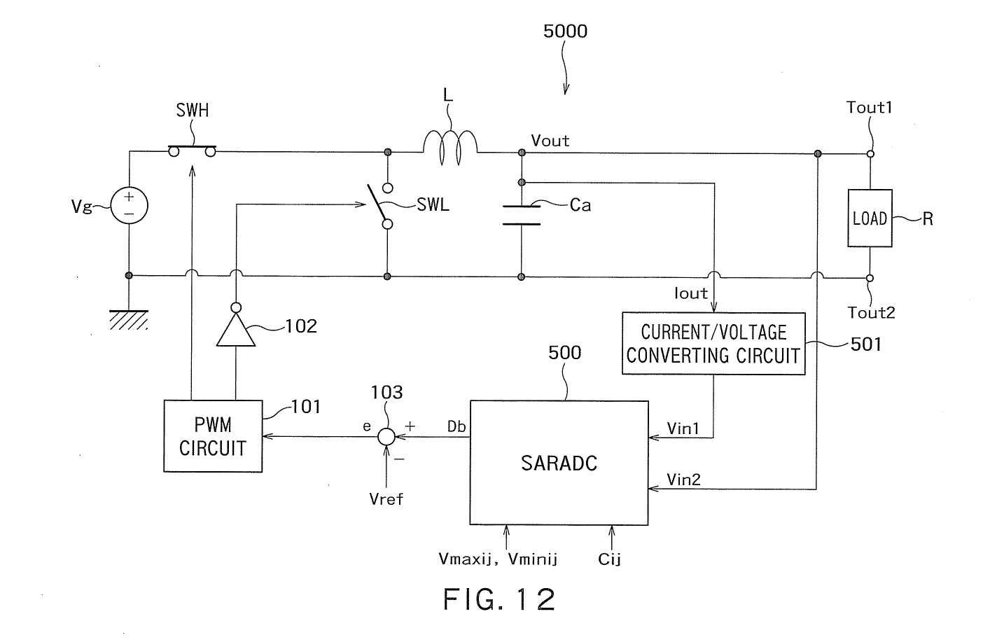

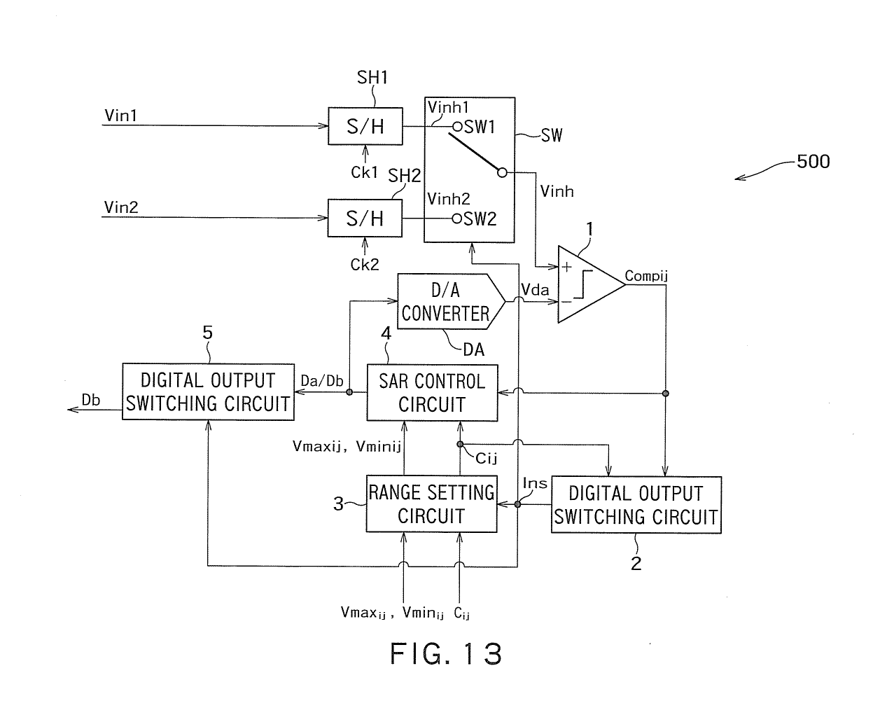

FIG. 12 shows an example of the configuration of a DC/DC converter 5000 according to a fifth embodiment. In FIG. 12, the same reference numerals as those of FIG. 1 denote the same components as those of the first embodiment.

As shown in FIG. 12, the DC/DC converter 5000 includes a successive approximation register A/D converter 500, a current/voltage converting circuit 501, a PWM circuit 101, an inverter 102, a comparator 103, a first output terminal Tout1, a second output terminal Tout2, a high-side switch SWH, a low-side switch SWL, a capacitor Ca, and an inductor L.

That is, the DC/DC converter 5000 further includes the current/voltage converting circuit 501, as compared with the DC/DC converter 1000 according to the second embodiment.

The current/voltage converting circuit 501 converts, for example, a current flowing to the capacitor Ca into a voltage and outputs a detection voltage (first voltage Vin1) according to a current (output current) flowing to the first output terminal Tout1.

The successive approximation register A/D converter 500 changes a first conversion range according to the detection voltage (first voltage Vin1). The successive approximation register A/D converter 500 receives the output voltage Vout (second voltage Vin2) and outputs a digital value Db that is obtained by executing an A/D conversion on the second voltage Vin2. The operation that the successive approximation register A/D converter 5000 executes the A/D conversion on the second voltage Vin2 to obtain a digital value Db is the same as that of the second embodiment.

The DC/DC converter 5000 can correspond to a rapid change in the output current. When the output current is rapidly changed, the output voltage Vout may be out of the first conversion range.

By changing the first conversion range following prediction of the change in the output voltage. Vout in advance such that the output voltage Vout is not out of the conversion range, the A/D conversion can be efficiently executed. In the case of the DC/DC converter, since the output voltage Vout has a capacity, a phase of the output current is more advanced by 90 degrees than a phase of the output voltage Vout.

Therefore, when the successive approximation register A/D converter 500 executes the A/D conversion on the voltage Vin1 corresponding to the output current and the rapid change is generated in the conversion value (digital value Da), the successive approximation register A/D converter 500 changes the conversion range of the output voltage Vout according to the change in the output current.

Thereby, the output voltage Vout does not go out of the conversion range and the conversion range can be appropriately set to correspond to any changes.

FIG. 13 shows an example of the configuration of the successive approximation register A/D converter 500 of the DC/DC converter 5000 shown in FIG. 12. In FIG. 13, the same reference numerals as those of FIG. 7 denote the same components as those of the second embodiment.

As shown in FIG. 13, the successive approximation register A/D converter 500 has a comparator 1, a within/outside range determining circuit 2, a range setting circuit 3, a SAR control circuit 4, a first sample and hold circuit SH1, a second sample and hold circuit SH2, a D/A converter DA, a switch circuit SW, and a digital output switching circuit 5.

The range setting circuit 3 is configured such that digital signals (minimum value Vminij and maximum value Vmaxij) to define a maximum value and a minimum value of the digital value (Dij) and conversion frequencies Cij corresponding to the execution frequencies of the A/D conversion in a certain conversion range are input from the outside of the successive approximation register A/D converter 100. The range setting circuit 3 receives the digital value Da output from the SAR control circuit 4.

The range setting circuit 3 sets the first conversion range on the basis of the result of the A/D conversion on the voltage Vin1 corresponding to the output current. Thereby, the conversion range of the output voltage Vout can be changed according to the change in the output current.

The digital output switching circuit 5 does not output the digital value Da that corresponds to the output current but outputs the digital value Db that corresponds to the output voltage Vout (second voltage Vin2).

Other basic operations of the successive approximation register A/D converter 500 are the same as that of the successive approximation register A/D converter 200 according to the second embodiment.

By applying the successive approximation register A/D converter 500 to the DC/DC converter 5000, the conversion range can be greatly reduced.

As described above, according to the successive approximation register A/D converter according to the fifth embodiment, the conversion ranges of the input signals can be appropriately set and the conversion frequencies of the input signals can be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A successive approximation register A/D converter that executes an A/D conversion on an analog signal, and that outputs an obtained digital value, the successive approximation register A/D converter comprising:
a first sample and hold circuit that receives a first voltage being an analog signal, and that outputs a sample and hold value obtained by sampling and holding the first voltage in synchronization with a first clock signal;
a D/A converter that outputs a conversion value obtained by executing a D/A conversion on the digital value;
a comparator that compares the sample and hold value and the conversion value, and that outputs a comparison result signal according to the comparison result;
a SAR control circuit that changes the digital value by the set change frequency in the set conversion range to carry out binary search for the sample and hold value with the conversion value according to the comparison result signal, and outputs the digital value;
a within/outside range determining circuit that determines whether the sample and hold value is within the set conversion range, on the basis of the comparison result signal and the conversion frequency, and outputs a determination signal according to the determination result; and
a range setting circuit that sets the conversion range on the basis of the determination signal,
wherein the SAR control circuit changes the digital value by the first conversion frequency in a first conversion range according to the comparison result signal, and outputs the digital value, and
wherein, when it is determined that the sample and hold value is out of the first conversion range according to the determination signal, the range setting circuit sets a second conversion range different from the first conversion range.

2. The successive approximation register A/D converter according to claim 1,
wherein a plurality of the second conversion ranges are set with different ranges,
wherein the within/outside range determining circuit outputs the determination signal according to a positional relationship of the first conversion range and the first sample and hold value, on the basis of the comparison result signals, and
wherein the range setting circuit selects and sets one second conversion range from the plurality of the second conversion ranges on the basis of the positional relationship, when it is determined that the first sample and hold value is out of the first conversion range according to the determination signal.

3. The successive approximation register A/D converter according to claim 1,
wherein the successive approximation register A/D converter further comprising:
a second sample and hold circuit that receives a second voltage being an analog signal, and that outputs a sample and hold value obtained by sampling and holding the second voltage in synchronization with a second clock signal having a cycle longer than a cycle of the first clock signal;
a switch circuit that switches an output of the first sample and hold circuit and an output of the second sample and hold circuit according to the determination signal, and that outputs the output value; and
a digital output switching circuit that switches the digital value corresponding to the output of the first sample and hold circuit and the digital value corresponding to the output of the second sample and hold circuit according to the determination signal, and that outputs the digital value,
wherein, when it is determined that the sample and hold value of the first sample and hold circuit is within the first conversion range according to the determination signal, the switch circuit switches the output from the output of the first sample and hold circuit to the output of the second sample and hold circuit, and that outputs the output value, and
wherein, when it is determined that the sample and hold value of the first sample and hold circuit is within the first conversion range according to the determination signal, the digital output switching circuit switches the digital value from the digital value corresponding to the output of the first sample and hold circuit to the digital value corresponding to the output of the second sample and hold circuit, and that outputs the digital value.

4. The successive approximation register A/D converter according to claim 2,
wherein the successive approximation register A/D converter further comprising:
a second sample and hold circuit that receives a second voltage being an analog signal, and that outputs a sample and hold value obtained by sampling and holding the second voltage in synchronization with a second clock signal having a cycle longer than a cycle of the first clock signal;
a switch circuit that switches an output of the first sample and hold circuit and an output of the second sample and hold circuit according to the determination signal, and that outputs the output value; and
a digital output switching circuit that switches the digital value corresponding to the output of the first sample and hold circuit and the digital value corresponding to the output of the second sample and hold circuit according to the determination signal, and that outputs the digital value,
wherein, when it is determined that the sample and hold value of the first sample and hold circuit is within the first conversion range according to the determination signal, the switch circuit switches the output from the output of the first sample and hold circuit to the output of the second sample and hold circuit, and that outputs the output value, and
wherein, when it is determined that the sample and hold value of the first sample and hold circuit is within the first conversion range according to the determination signal, the digital output switching circuit switches the digital value from the digital value corresponding to the output of the first sample and hold circuit to the digital value corresponding to the output of the second sample and hold circuit, and that outputs the digital value.

5. A DC/DC converter that controls a power supply voltage of a power supply for supplying the power supply voltage to a load, the DC/DC converter comprising:
a first output terminal that is connected to a first end of a capacitor;
a second output terminal that is connected to a second end of the capacitor;
a high-side switch having a first end connected to a first end of the power supply, and having a second end connected to a second end of an inductor, the inductor having a first end connected to the first output terminal;
a low-side switch having a first end connected to the second end of the high-side switch, and having a second end connected to a second end of the power supply and the second end of the capacitor;
a successive approximation register A/D converter that executes an A/D conversion on a first voltage being an analog signal of the first output terminal, and that outputs an obtained digital value;
a comparator that calculates a difference of the digital value and a reference voltage value, and that outputs an obtained error voltage; and
a PWM circuit that complementarily controls turning ON/OFF of the high-side switch and the low-side switch, on the basis of the error voltage,
wherein the successive approximation register A/D converter comprising:
a first sample and hold circuit that receives a first voltage being an analog signal, and that outputs a sample and hold value obtained by sampling and holding the first voltage in synchronization with a first clock signal;
a D/A converter that outputs a conversion value obtained by executing a D/A conversion on the digital value;
a comparator that compares the sample and hold value and the conversion value, and that outputs a comparison result signal according to the comparison result;
a SAR control circuit that changes the digital value by the set change frequency in the set conversion range to carry out binary search for the sample and hold value with the conversion value according to the comparison result signal, and outputs the digital value;
a within/outside range determining circuit that determines whether the sample and hold value is within the set conversion range, on the basis of the comparison result signal and the conversion frequency, and outputs a determination signal according to the determination result; and
a range setting circuit that sets the conversion range on the basis of the determination signal,
wherein the SAR control circuit changes the digital value by the first conversion frequency in a first conversion range according to the comparison result signal, and outputs the digital value, and
wherein, when it is determined that the sample and hold value is out of the first conversion range according to the determination signal, the range setting circuit sets a second conversion range different from the first conversion range.

6. The DC/CD converter according to claim 5,
wherein the successive approximation register A/D converter further comprising:
a second sample and hold circuit that receives a second voltage being an analog signal, and that outputs a sample and hold value obtained by sampling and holding the second voltage in synchronization with a second clock signal having a cycle longer than a cycle of the first clock signal;
a switch circuit that switches an output of the first sample and hold circuit and an output of the second sample and hold circuit according to the determination signal, and that outputs the output value; and
a digital output switching circuit that switches the digital value corresponding to the output of the first sample and hold circuit and the digital value corresponding to the output of the second sample and hold circuit according to the determination signal, and that outputs the digital value,
wherein, when it is determined that the sample and hold value of the first sample and hold circuit is within the first conversion range according to the determination signal, the switch circuit switches the output from the output of the first sample and hold circuit to the output of the second sample and hold circuit, and that outputs the output value,
wherein, when it is determined that the sample and hold value of the first sample and hold circuit is within the first conversion range according to the determination signal, the digital output switching circuit switches the digital value from the digital value corresponding to the output of the first sample and hold circuit to the digital value corresponding to the output of the second sample and hold circuit, and that outputs the digital value, and
wherein a temperature sensor outputs the second voltage according to the temperature of the DC/DC converter.

7. The DC/CD converter according to claim 5, further comprising a soft start control circuit that sets the minimum value of the first conversion range to a ground voltage and sets a maximum value of the first conversion range to a minimum value of the second conversion range, when the first voltage increases from the ground voltage.

8. The DC/CD converter according to claim 5, further comprising a load prediction control circuit that adjusts a first conversion range according to a prediction value of the increase/decrease of a load current flowing to a load.

9. The DC/CD converter according to claim 5, further comprising a current/voltage converting circuit that outputs a detection voltage according to a current flowing to the first output terminal,
wherein the successive approximation register A/D converter changes a first conversion range according to the detection voltage.

10. The DC/CD converter according to claim 5,
wherein a plurality of the second conversion ranges are set with different ranges,
wherein the within/outside range determining circuit outputs the determination signal according to a positional relationship of the first conversion range and the first sample and hold value, on the basis of the comparison result signals, and
wherein the range setting circuit selects and sets one second conversion range from the plurality of the second conversion ranges on the basis of the positional relationship, when it is determined that the first sample and hold value is out of the first conversion range according to the determination signal.

11. The DC/CD converter according to claim 6,
wherein a plurality of the second conversion ranges are set with different ranges,
wherein the within/outside range determining circuit outputs the determination signal according to a positional relationship of the first conversion range and the first sample and hold value, on the basis of the comparison result signals, and
wherein the range setting circuit selects and sets one second conversion range from the plurality of the second conversion ranges on the basis of the positional relationship, when it is determined that the first sample and hold value is out of the first conversion range according to the determination signal.

12. The DC/CD converter according to claim 7,
wherein a plurality of the second conversion ranges are set with different ranges,
wherein the within/outside range determining circuit outputs the determination signal according to a positional relationship of the first conversion range and the first sample and hold value, on the basis of the comparison result signals, and
wherein the range setting circuit selects and sets one second conversion range from the plurality of the second conversion ranges on the basis of the positional relationship, when it is determined that the first sample and hold value is out of the first conversion range according to the determination signal.

13. The DC/CD converter according to claim 8,
wherein a plurality of the second conversion ranges are set with different ranges,
wherein the within/outside range determining circuit outputs the determination signal according to a positional relationship of the first conversion range and the first sample and hold value, on the basis of the comparison result signals, and
wherein the range setting circuit selects and sets one second conversion range from the plurality of the second conversion ranges on the basis of the positional relationship, when it is determined that the first sample and hold value is out of the first conversion range according to the determination signal.

14. The DC/CD converter according to claim 9,
wherein a plurality of the second conversion ranges are set with different ranges,
wherein the within/outside range determining circuit outputs the determination signal according to a positional relationship of the first conversion range and the first sample and hold value, on the basis of the comparison result signals, and
wherein the range setting circuit selects and sets one second conversion range from the plurality of the second conversion ranges on the basis of the positional relationship, when it is determined that the first sample and hold value is out of the first conversion range according to the determination signal.

15. A successive approximation register A/D converter that executes an A/D conversion on an analog signal, and that outputs an obtained digital value, the successive approximation register A/D converter comprising:
a first sample and hold circuit that receives a first voltage being an analog signal, and that outputs a sample and hold value obtained by sampling and holding the first voltage in synchronization with a first clock signal;
a D/A converter that outputs a conversion value obtained by executing a D/A conversion on the digital value;
a comparator that compares the sample and hold value and the conversion value, and that outputs a comparison result signal according to the comparison result;
a SAR control circuit that changes the digital value by the set change frequency in the set conversion range to carry out binary search for the sample and hold value with the conversion value according to the comparison result signal, and outputs the digital value;
a within/outside range determining circuit that determines whether the sample and hold value is within the set conversion range, on the basis of the comparison result signal and the conversion frequency, and outputs a determination signal according to the determination result; and
a range setting circuit that sets the conversion range on the basis of the determination signal.

16. The successive approximation register A/D converter according to claim 15,
wherein the successive approximation register A/D converter further comprising:
a second sample and hold circuit that receives a second voltage being an analog signal, and that outputs a sample and hold value obtained by sampling and holding the second voltage in synchronization with a second clock signal having a cycle longer than a cycle of the first clock signal;
a switch circuit that switches an output of the first sample and hold circuit and an output of the second sample and hold circuit according to the determination signal, and that outputs the output value; and
a digital output switching circuit that switches the digital value corresponding to the output of the first sample and hold circuit and the digital value corresponding to the output of the second sample and hold circuit according to the determination signal, and that outputs the digital value.
